(19) United States
(12) Patent Application Publication
(10) Pub. No.: US 2026/0279481 A1
(43) Pub. Date: Sep. 17, 2026

(54) MEMORY DEVICE AND OPERATING METHOD OF THE SAME

(71) Applicant: SK hynix Inc., Icheon-si (KR)

(72) Inventors: Beom Seok LEE, Icheon-si (KR); Myoungsub KIM, Icheon-si (KR); Mu Hui PARK, Icheon-si (KR); In Seon YEO, Icheon-si (KR)

(21) Appl. No.: 19/364,749

(22) Filed: Oct. 21, 2025

(30) Foreign Application Priority Data
Mar. 14, 2025 (KR) 10-2025-0033191

(51) Int. Cl. G11C 29/52; G11C 13/00

(52) U.S. Cl. CPC G11C 29/52; G11C 13/0038; G11C 13/004; G11C 2013/0045

(57) ABSTRACT

An operating method of a memory device includes receiving a first read command, providing a read voltage to a first memory cell based on the first read command, determining whether the first memory cell is in a set state, and providing a backward pulse to the first memory cell that has been determined to be in the set state.

### CROSS-REFERENCE TO RELATED APPLICATION

This application claims priority under 35 U.S.C. §119(a) to Korean Patent Application No. 10-2025-0033191, filed in the Korean Intellectual Property Office on March 14, 2025, the entire contents of which are incorporated herein by reference.

### BACKGROUND

### Technical Field

Embodiments relate to an integrated circuit technology and, more particularly, to a memory device and an operating method of the same.

### Related Art

Recently, as an electronic device is reduced in size, has lower power consumption and higher performance, and is diversified, memory capable of storing information is desirable for various electronic devices, such as computers and portable communication devices. Furthermore, research on memory having various characteristics continues to be conducted.

Memory that is being researched also includes memory capable of storing data by using a characteristic in which the memory switches between different resistance states depending on a voltage or current thereto. Such memory includes resistive random access memory (RRAM), phase change random access memory (PRAM), ferroelectric random access memory (FRAM), magnetic random access memory (MRAM), an E-fuse, and selector only memory (SOM).

### SUMMARY

In an embodiment, an operating method of a memory device may include receiving a first read command, providing a read voltage to a first memory cell based on the first read command, determining whether the first memory cell is in a set state, and providing a backward pulse to the first memory cell that has been determined to be in the set state.

In an embodiment, a memory device may include a memory cell electrically connected between a bit line and a word line, a voltage change circuit configured to provide a first voltage to one of the bit line and the word line and configured to provide a second voltage to the other of the bit line and the word line, a sense amplifier configured to generate a signal indicating a state of the memory cell, and a control circuit configured to control the voltage change circuit to provide a read voltage to the memory cell after the start of a read operation and configured to control the voltage change circuit to sequentially provide a backward pulse and a forward pulse to the memory cell based on the state of the memory cell.

### BRIEF DESCRIPTION OF THE DRAWINGS

FIG. 1 is a diagram for describing a memory cell of a memory device according to an embodiment of the present disclosure.

FIGS. 2 and 3 are diagrams for describing write operations of a memory device according to embodiments of the present disclosure.

FIG. 4 is a diagram for describing a read operation of a memory device according to an embodiment of the present disclosure.

FIG. 5 is a diagram for describing an issue that occurs due to repeated read operations.

FIG. 6 is a flowchart for describing an operation of a memory device according to an embodiment of the present disclosure.

FIG. 7 a diagram for illustrating a memory device according to an embodiment of the present disclosure.

FIG. 8 is a diagram illustrating a voltage change circuit illustrated in FIG. 7 according to an embodiment of the present disclosure.

FIGS. 9 and 10 are timing diagrams for describing operations of the memory device according to embodiments of the present disclosure.

### DETAILED DESCRIPTION

Hereinafter, some embodiments of the present disclosure are described with reference to the accompanying drawings.

Embodiments of the present disclosure relate to a technology in which a backward pulse and a forward pulse are sequentially provided to a memory cell determined to be in a specific state (e.g., a set state) after the start of a read operation.

It is possible to prevent an error in a read operation which may occur because the level of the threshold voltage of a memory cell in a set state increases due to repeated read operations.

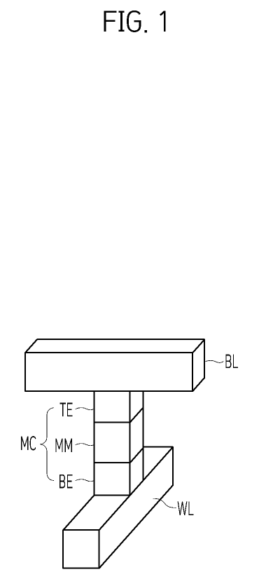

FIG. 1 is a diagram for describing a memory cell of a memory device according to an embodiment of the present disclosure.

Referring to FIG. 1, a memory cell MC of a memory device according to an embodiment of the present disclosure may be disposed between a bit line BL and a word line WL. Furthermore, the memory cell MC may be electrically connected to the bit line BL and the word line WL. In FIG. 1, the bit line BL has been illustrated as being disposed over the word line WL, but may be disposed under the word line WL according to an embodiment. Furthermore, each of the bit line BL and the word line WL may include a conductive material.

The memory cell MC may include a first electrode TE, a memory material MM, and a second electrode BE. The memory material MM may be disposed between the first electrode TE and the second electrode BE. In this case, each of the first electrode TE and second electrode BE may include a conductive material. The level of the threshold voltage of the memory material MM may be changed depending on the direction of a current that flows through the memory material MM. The memory material MM may include a chalcogenide-series material.

For example, the second electrode BE may be formed on the word line WL. The memory material MM may be formed on the second electrode BE. The first electrode TE may be formed on the memory material MM. The bit line BL may be formed on the first electrode TE. In this case, the first electrode TE at a higher location than the second electrode BE may be named an upper electrode TE. The second electrode BE at a lower location than the first electrode TE may be named a lower electrode BE.

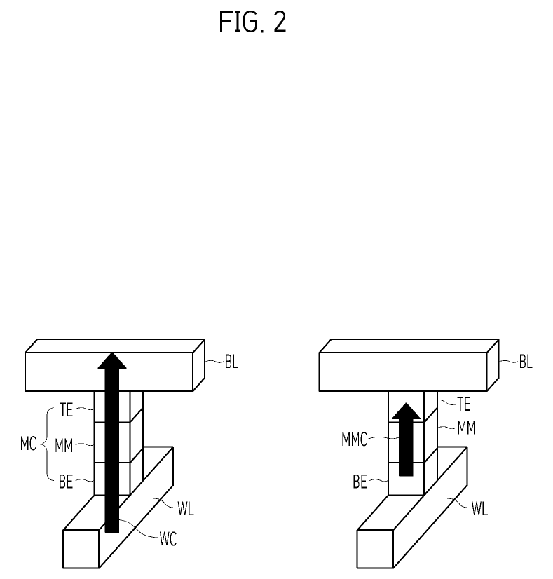

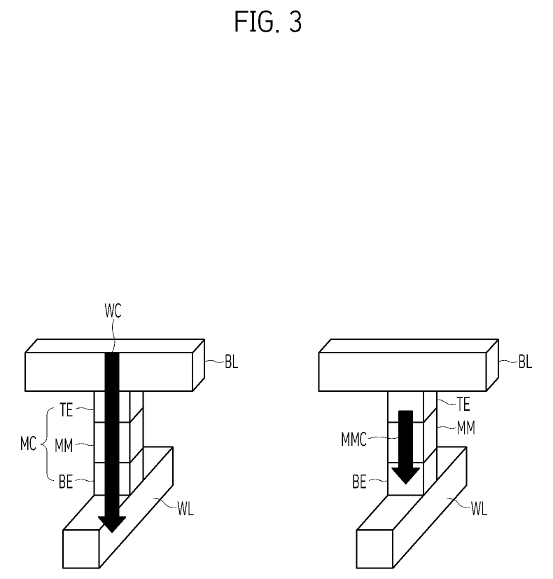

FIGS. 2 and 3 are diagrams for describing write operations of a memory device according to embodiments of the present disclosure.

FIG. 2 may be a diagram illustrating a write operation (e.g., a reset write operation) in which a write current WC flows from the word line WL to the bit line BL through the memory cell MC. The write operation may be an operation of providing the word line WL and the bit line BL with voltages such that a difference between the voltage levels of the word line WL and the bit line BL is greater than a voltage difference sufficient to turn on the memory cell MC. In this case, the word line WL may be provided with a voltage higher than the voltage of the bit line BL.

The write operation may be an operation of changing a memory material characteristic MMC of the memory material MM so that a current better flows in a first direction than in a second direction. In this case, the first direction may be a direction in which the current flows from the word line WL to the bit line BL through the memory material MM. The second direction may be a direction in which the current flows from the bit line BL to the word line WL through the memory material MM.

FIG. 3 may be a diagram illustrating a write operation (e.g., a set write operation) in which the write current WC flows from the bit line BL to the word line WL through the memory cell MC. The write operation may be an operation of providing the bit line BL and the word line WL with voltages such that a difference between the voltage levels of the bit line BL and the word line WL is greater than a voltage difference sufficient to turn on the memory cell MC. In this case, the bit line BL may be provided with a voltage higher than the voltage of the word line WL.

The write operation may be an operation of changing the memory material characteristic MMC of the memory material MM so that the current better flows in the second direction than in the first direction. In this case, the first direction may be a direction in which the current flows from the word line WL to the bit line BL through the memory material MM. The second direction may be a direction in which the current flows from the bit line BL to the word line WL through the memory material MM.

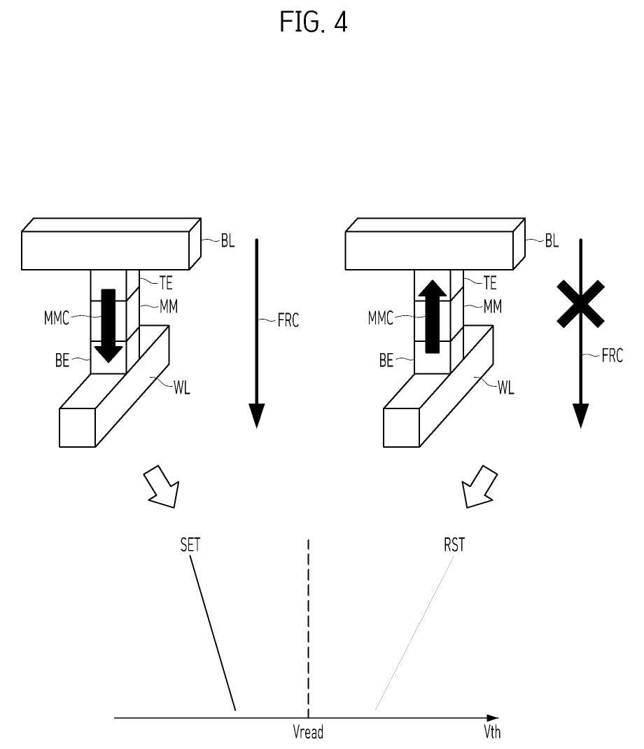

FIG. 4 is a diagram for describing a read operation of a memory device according to an embodiment of the present disclosure.

Referring to FIG. 4, the read operation may be an operation of determining the state of the memory cell MC by providing the bit line BL with a voltage having a higher level than the voltage of the word line WL. In the embodiment of FIG. 4, the read operation may be an operation of making a read current FRC flow in the same direction as the current direction WC after the start of the write operation illustrated in FIG. 3. Furthermore, a difference between the voltage levels of the bit line BL and the word line WL after the start of the read operation may correspond to the level of a read voltage Vread. The read voltage Vread may have a level between the level of the threshold voltage of the memory cell MC according to a first write operation (e.g., the reset write operation described with reference to FIG. 2) and the level of the threshold voltage of the memory cell MC according to a second write operation (e.g., the set write operation described with reference to FIG. 3).

Accordingly, when a read operation is performed on the memory cell MC having a memory material characteristic MMC changed as illustrated in FIG. 4 through a set write operation (e.g., the set write operation of FIG. 3), the read current FRC may flow from the bit line BL to the word line WL through the memory cell MC that is turned on. At this time, the memory cell MC may be turned on because the threshold voltage of the memory cell MC having the memory material characteristic MMC changed by a set write operation, such as that described with reference to FIG. 3, has a lower level than the read voltage Vread.

When a read operation is performed on the memory cell MC having the memory material characteristic MMC changed as illustrated in FIG. 4 through a reset write operation (e.g., the reset write operation of FIG. 2), the read current FRC might not substantially flow. At this time, the memory cell MC might not be turned on because the threshold voltage of the memory cell MC having the memory material characteristic MMC changed by a reset write operation, such as that described with reference to FIG. 2, has a higher level than the read voltage Vread. Accordingly, the read current FRC might not substantially flow.

The state of a memory cell MC with a threshold voltage having a lower level than the read voltage Vread may be called a set state SET. The state of a memory cell MC having a threshold voltage having a higher level than the read voltage Vread may be called a reset state RST.

That is, the memory cell MC may change into the set state SET through a write operation, such as that described with reference to FIG. 3. Furthermore, the memory cell MC may change into the reset state RST through a write operation, such as that described with reference to FIG. 4. In this case, the write operation of changing the state of the memory cell MC into the set state SET may be named a set write operation. The write operation of changing the state of the memory cell MC into the reset state RST may be named a reset write operation.

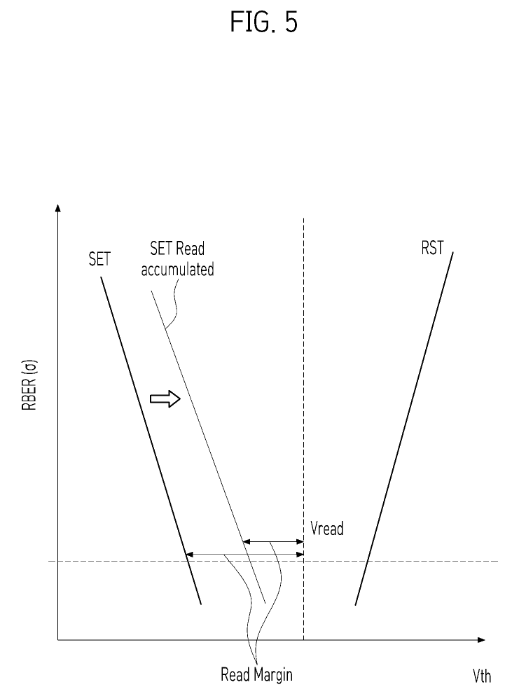

FIG. 5 is a diagram for describing an issue that may occur due to repeated read operations.

In the read operation, as described above, when the memory cell MC is turned on, a current may flow through the memory cell MC that is turned on in the same direction as the direction of the set write operation (refer to FIG. 3). A difference between voltage levels at both ends of the memory cell MC, that is, a difference between the voltage levels of the bit line BL and the word line WL, after the start of a read operation may be smaller than a difference between the voltage levels of the bit line BL and the word line WL after the start of a set write operation. Without wishing to be limited by theory, the reason for this may be that a difference between voltage levels at both ends of the memory cell MC, that is, a difference between the voltage levels of the bit line BL and the word line WL, after the start of a set write operation may be sufficient to turn on the memory cell MC in the reset state, and a difference between the voltage levels of the bit line BL and the word line WL after the start of a read operation may be sufficient to turn on the memory cell MC in the set state while keeping the memory cell MC in the reset state turned off.

Accordingly, after the start of a read operation, the level of the threshold voltage of the memory cell MC that is turned on by a difference between the voltage levels of the bit line BL and the word line WL, which is smaller than a difference between the voltage levels of the bit line BL and the word line WL after the start of a set write operation, may increase as the read operation is repeated.

Such a phenomenon may reduce a read margin between the read voltage Vread and the threshold voltage (Read accumulated) of a memory cell in the set state, which is increased by the repeated read operations.

As the read margin is reduced, the probability that an error may occur in determining the set state of a memory cell after the start of a read operation may be increased.

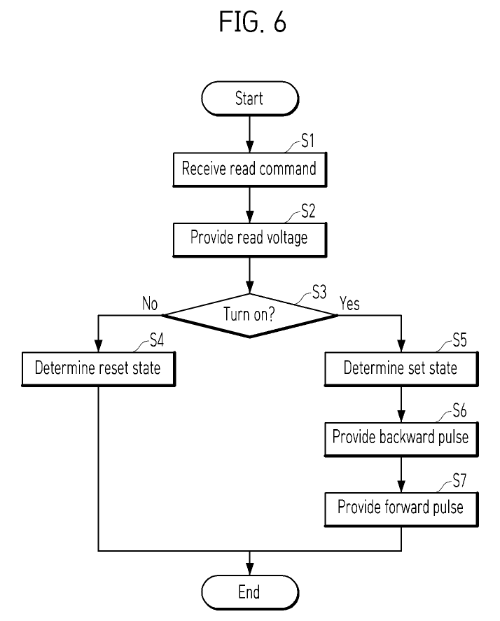

FIG. 6 is a flowchart for describing an operation of a memory device according to an embodiment of the present disclosure.

Referring to FIG. 6, an operating method of the memory device according to an embodiment of the present disclosure may include a read command reception process S1, a read voltage provision process S2, a process S3 of checking whether a memory cell has been turned on, a reset determination process S4, a set determination process S5, a backward pulse provision process S6, and a forward pulse provision process S7.

The read command reception process S1 may include a process of the memory device receiving a read command and an address.

The read voltage provision process S2 may include a process of providing the read voltage Vread to a memory cell MC based on the read command to perform a read operation. For example, the read voltage provision process S2 may include a process of providing the read voltage Vread to a selected memory cell MC based on the address. In this case, the read voltage Vread may be provided to both ends of the memory cell MC, that is, a selected bit line BL and a selected word line WL, so that a difference between the voltage levels of the selected bit line BL and the selected word line WL corresponds to the level of the read voltage Vread. Furthermore, the selected bit line BL may be provided with a voltage having a higher level than a voltage provided to the selected word line WL.

The method may further include determining whether the selected memory cell MC is in a specific state (e.g., a set state), as will be described below with reference to S3, S4, and S5 in the embodiment of FIG. 6. The process S3 of checking whether the memory cell MC has been turned on is a process of checking whether the selected memory cell MC has been turned on, and may include a process of checking whether the selected memory cell MC has been turned on or turned off.

When it is checked that the selected memory cell MC has not been turned on (No) in the process S3 of checking whether the selected memory cell MC has been turned on, the reset determination process S4 may be performed.

The reset determination process S4 may include a process of determining that the state of the memory cell MC is the reset state. The level of the read voltage Vread is a level between the levels of the threshold voltage of the memory cell MC in the set state and the threshold voltage of the memory cell MC in the reset state. Accordingly, when the read voltage Vread is provided to the memory cell MC, the state of the memory cell MC that has not been turned on may be determined to be the reset state.

When it is checked that the selected memory cell MC has been turned on (Yes) in the process S3 of checking whether the selected memory cell MC has been turned on, the set determination process S5 may be performed.

The set determination process S5 may include a process of determining that the state of the memory cell MC is the set state. The level of the read voltage Vread is a level between the levels of the threshold voltage of the memory cell MC in the set state and the threshold voltage of the memory cell MC in the reset state. Accordingly, when the read voltage Vread is provided to the memory cell MC, the state of the memory cell MC that is turned on may be determined to be the set state.

After the set determination process S5 is performed, the backward pulse provision process S6 and the forward pulse provision process S7 may be sequentially performed. In some embodiments, in the backward pulse provision process S6, a backward pulse may be provided to the memory cell MC, when the memory cell MC has been determined to be in the set state. Subsequently, in the forward pulse provision process S7, a forward pulse may be provided to the memory cell MC.

The backward pulse provision process S6 and the forward pulse provision process S7 may each include a process of turning on a memory cell determined to be in the set state. In this case, in the backward pulse provision process S6 and the forward pulse provision process S7, the directions of currents that flow through a turned-on memory cell may be opposite to each other.

The backward pulse provision process S6 may include a process of making a current flow in a direction opposite to a direction of a current that flows after the start of a read operation by turning on a memory cell determined to be in the set state. In other words, a direction of a current that passes through the memory cell MC when the backward pulse is provided to the memory cell MC is opposite to a direction of a current when a read voltage is provided to the memory cell MC. If the read voltage provision process S2 is an operation of providing the bit line BL with a voltage having a higher level than a voltage provided to the word line WL, the backward pulse provision process S6 may include a process of turning on a memory cell in the set state by providing the word line WL with a voltage having a higher level than a voltage provided to the bit line BL. In some embodiments, in the backward pulse provision process S6, a difference between voltage levels applied to both ends of the memory cell MC may be equal to or smaller than a difference between the voltage levels of the bit line BL and the word line WL after the start of a reset write operation. In some embodiments, the backward pulse provision process S6 may include a process of changing the set state of the memory cell into the reset state.

After the backward pulse provision process S6, the forward pulse provision process S7 may be performed.

The forward pulse provision process S7 may include a process of turning on the memory cell MC so that a current flows through the memory cell MC on which the backward pulse provision process S6 has been performed in a direction opposite to the direction of the current in the backward pulse provision process S6. In other words, a direction of a current that passes through the memory cell MC when the forward pulse is provided to the memory cell MC is identical with a direction of a current when the read voltage is provided to the memory cell MC. If the backward pulse provision process S6 is an operation of providing the word line WL with a voltage having a higher level a voltage provided to the bit line BL, the forward pulse provision process S7 may include a process of turning on the memory cell MC on which the backward pulse provision process S6 has been performed by providing the bit line BL with a voltage having a higher level than a voltage applied to the word line WL. In some embodiments, in the forward pulse provision process S7, a difference between voltage levels applied to both ends of the memory cell MC may be equal to or smaller than a difference between the voltage levels of the bit line BL and the word line WL after the start of a set write operation. In some embodiments, the forward pulse provision process S7 may include a process of changing the state of the memory cell on which the backward pulse provision process S6 has been performed into the set state.

As a result, the memory device according to an embodiment of the present disclosure may perform an operation of changing the state of a memory cell determined to be in the set state into the reset state by providing a backward pulse after the start of a read operation and then changing the reset state of the memory cell into the set state again by providing a forward pulse. The level of the threshold voltage of the memory cell MC having the set state changed into the reset state and then changed into the set state again may be lower than the level of a threshold voltage increased by repeated read operations. Accordingly, a read margin may be ensured in memory cell(s) according to embodiments of the present disclosure to substantially prevent an error associated with repeated read operations.

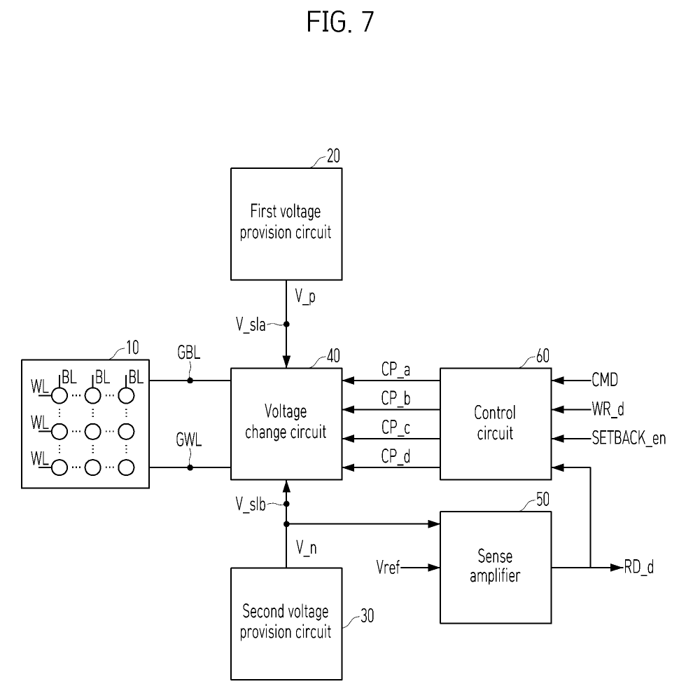

FIG. 7 a diagram for illustrating a memory device according to an embodiment of the present disclosure.

Referring to FIG. 7, the memory device according to an embodiment of the present disclosure may include a cell array 10, a first voltage provision circuit 20, a second voltage provision circuit 30, a voltage change circuit 40, a sense amplifier 50, and a control circuit 60.

The cell array 10 may include at least one memory cell MC that is electrically connected between a bit line BL and a word line WL. In this case, the bit line BL may be electrically connected to a global bit line GBL. The word line WL may be electrically connected to a global word line GWL. For example, the bit line BL may be electrically connected to or separated from the global bit line GBL based on an address (not illustrated). Furthermore, the word line WL may also be electrically connected to or separated from the global word line GBL based on the address (not illustrated).

The first voltage provision circuit 20 may provide the voltage change circuit 40 with a first voltage V_p through a first voltage line V_sla.

The second voltage provision circuit 30 may provide the voltage change circuit 40 with a second voltage V_n through a second voltage line V_slb. In this case, the first voltage V_p may have a higher level than the second voltage V_n. The first voltage V_p may have a higher level than the second voltage V_n. The first voltage V_p may be a positive voltage, and the second voltage V_n may be a negative voltage.

The voltage change circuit 40 may provide the first voltage V_p to one of the global bit line GBL and the global word line GWL and provide the second voltage V_n to the other of the global bit line GBL and the global word line GWL, based on a first polarity change control signal CP_a, a second polarity change control signal CP_b, a third polarity change control signal CP_c, and a fourth polarity change control signal CP_d. For example, the voltage change circuit 40 may provide the second voltage V_n to the global word line GWL when providing the first voltage V_p to the global bit line GBL based on the first to fourth polarity change control signals CP_a, CP_b, CP_c, and CP_d. Furthermore, the voltage change circuit 40 may provide the second voltage V_n to the global bit line GBL when providing the first voltage V_p to the global word line GWL based on the first to fourth polarity change control signals CP_a, CP_b, CP_c, and CP_d.

The sense amplifier 50 may identify data stored in the memory cell MC after the start of a read operation. For example, the sense amplifier 50 may identify data stored in the memory cell MC by comparing the levels of the second voltage line V_slb and a reference voltage Vref after the start of a read operation, and may output the results of the identification as read data RD_d. In some embodiments, the sense amplifier 50 may generate a signal indicating a state of a memory cell. More specifically, the sense amplifier 50 may output a signal having a specific level (e.g., a high level) as the read data RD_d after the start of a read operation. In some embodiments, when the data stored in the memory cell MC are set data, the sense amplifier 50 may output the signal having the specific level as the read data RD_d. When the data stored in the memory cell MC are reset data, the sense amplifier 50 may change the level of the signal and output the signal having the changed level as the read data RD_d. That is, the sense amplifier 50 may maintain the level of the signal that is output as the read data RD_d when the data stored in the memory cell MC are set data, and may change the level of the signal that is output as the read data RD_d, for example, from a high level to a low level when the data stored in the memory cell MC are reset data. More specifically, for example, after the start of a read operation, the sense amplifier 50 may output the read data RD_d having a high level when the memory cell MC is turned on, that is, when it is checked that the state of the memory cell MC is the set state, and may output the read data RD_d having a low level when the memory cell MC is turned off, that is, when it is checked that the state of the memory cell MC is the reset state.

The control circuit 60 may generate the first to fourth polarity change control signals CP_a, CP_b, CP_c, and CP_d based on a command CMD, write data WR_d, the read data RD_d, and a setback control signal SETBACK_en, and may provide the first to fourth polarity change control signals CP_a, CP_b, CP_c, and CP_d to the voltage change circuit 40.

For example, when the command CMD is a write command, the control circuit 60 may generate the first to fourth polarity change control signals CP_a, CP_b, CP_c, and CP_d based on the write data WR_d. More specifically, when the command CMD is a write command and the write data WR_d are reset data, the control circuit 60 may provide the voltage change circuit 40 with the first to fourth polarity change control signals CP_a, CP_b, CP_c, and CP_d to provide the first voltage V_p to the global word line GWL and provide the second voltage V_n to the global bit line GBL.

Furthermore, when the command CMD is a write command and the write data WR_d are set data, the control circuit 60 may provide the voltage change circuit 40 with the first to fourth polarity change control signals CP_a, CP_b, CP_c, and CP_d to provide the first voltage V_p to the global bit line GBL and provide the second voltage V_n to the global word line GWL.

When the command CMD is a read command, the control circuit 60 may generate the first to fourth polarity change control signals CP_a, CP_b, CP_c, and CP_d based on the setback control signal SETBACK_en and the read data RD_d.

For example, when the command CMD is a read command and the setback control signal SETBACK_en is enabled, the control circuit 60 may provide the voltage change circuit 40 with the first to fourth polarity change control signals CP_a, CP_b, CP_c, and CP_d to provide the first voltage V_p to the global bit line GBL and provide the second voltage V_n to the global word line GWL in order to determine the state of the memory cell MC.

At this time, when it is checked that the read data RD_d are set data, the control circuit 60 may provide the voltage change circuit 40 with the first to fourth polarity change control signals CP_a, CP_b, CP_c, and CP_d to provide the first voltage V_p to the global word line GWL and provide the second voltage V_n to the global bit line GBL during a first given (e.g., set) time interval. Thereafter, during a second given (e.g., set) time interval, the control circuit 60 may provide the voltage change circuit 40 with the first to fourth polarity change control signals CP_a, CP_b, CP_c, and CP_d to provide the first voltage V_p to the global bit line GBL and provide the second voltage V_n to the global word line GWL. In this case, a first difference between the levels of the first voltage V_p and the second voltages V_n that are provided to the global bit line GBL and the global word line GWL during the first set time interval, or a second difference between the levels of the first voltage V_p and the second voltages V_n during a second time interval, or both, may be greater than a difference between the levels of the first voltage V_p and the second voltages V_n, which determines the state of the memory cell MC.

As a result, when the read command is received and the read data RD_d are identified as the set data in the state in which the setback control signal SETBACK_en has been enabled, the control circuit 60 may control the voltage change circuit 40 so that a backward pulse is provided to the memory cell and then a forward pulse is provided to the memory cell. In this case, an operation of providing the backward pulse may include an operation of providing the first voltage V_p to the word line WL connected to the global word line GWL by providing the first voltage V_p to the global word line GWL during the first set time interval and simultaneously providing the second voltage V_n to the bit line BL connected to the global bit line GBL by providing the second voltage V_n to the global bit line GBL. An operation of providing the forward pulse may include an operation of providing the first voltage V_p to the bit line BL connected to the global bit line GBL by providing the first voltage V_p to the global bit line GBL during the second set time interval and simultaneously providing the second voltage V_n to the word line WL connected to the global word line GWL by providing the second voltage V_n to the global word line GWL.

When the read data RD_d are reset data and the read data RD_d are identified as set data in the state in which the setback control signal SETBACK_en has been disabled, the control circuit 60 may control the voltage change circuit 40 so that a backward pulse and a forward pulse are not provided to the memory cell MC.

As described above, the voltage change circuit 40, the sense amplifier 50, and the control circuit 60, among the components of the memory device according to an embodiment of the present disclosure, control voltages provided to the global bit line GBL and the global word line GWL, respectively, based on a read command and read data. Accordingly, the voltage change circuit 40, the sense amplifier 50, and the control circuit 60 may be named a voltage supply circuit. In some embodiments, such a voltage supply circuit may receive a read command, provide a read voltage to the memory cell based on the read command to perform a read operation, determine whether the memory cell is in a set state, and provide a backward pulse to the memory cell when the memory cell has been determined to be in the set state. Such a voltage supply circuit may further provide a forward pulse to the first memory cell to which the backward pulse has been provided.

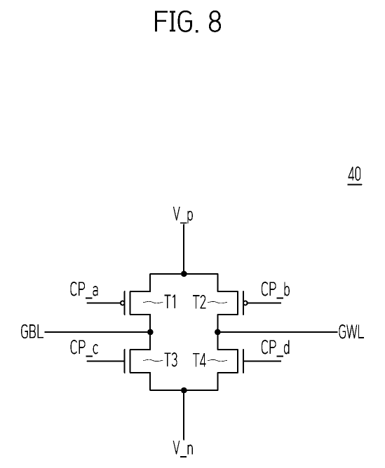

FIG. 8 is a diagram illustrating the voltage change circuit 40 illustrated in FIG. 7 according to an embodiment of the present disclosure.

The voltage change circuit 40 of the memory device, which is illustrated in FIG. 8, is merely an embodiment of the present disclosure. However, various embodiments of the present disclosure are not limited to the embodiment of FIG. 8.

Referring to FIG. 8, the voltage change circuit 40 may include first, second, third, and fourth transistors T1, T2, T3, and T4. In the embodiment of FIG. 8, the first transistor T1 and the second transistor T2 that provide the first voltage V_p to one of the global bit line GBL and the global word line GWL may each be a P type transistor. Furthermore, the third transistor T3 and the fourth transistor T4 that provide the second voltage V_n to one of the global bit line GBL and the global word line GWL may each be an N type transistor.

The first transistor T1 may have a gate to which the first polarity change control signal CP_a is input and a source to which the first voltage V_p is input.

The second transistor T2 may have a gate to which the second polarity change control signal CP_b is input and a source to which the first voltage V_p is input. In this case, the sources of the first transistor T1 and the second transistor T2 may be commonly connected. The first voltage V_p may be applied to a node at which the sources of the first transistor T1 and the second transistor T2 are commonly connected.

The third transistor T3 may have a gate to which the third polarity change control signal CP_c is input and a source to which the second voltage V_n is input.

The fourth transistor T4 may have a gate to which the fourth polarity change control signal CP_d is input and a source to which the second voltage V_n is input. In this case, the sources of the third transistor T3 and the fourth transistor T4 may be commonly connected. The second voltage V_n may be applied to a node at which the sources of the third transistor T3 and the fourth transistor T4 are commonly connected.

A drain of the first transistor T1 and a drain of the third transistor T3 may be commonly connected to the global bit line GBL. Furthermore, a drain of the second transistor T2 and a drain of the fourth transistor T4 may be commonly connected to the global word line GWL.

The voltage change circuit 40 constructed as described above according to an embodiment of the present disclosure may provide the first voltage V_p to one of the global bit line GBL and the global word line GWL and provide the second voltage V_n to the other of the global bit line GBL and the global word line GWL, based on the first to fourth polarity change control signals CP_a, CP_b, CP_c, and CP_d provided by the control circuit 60.

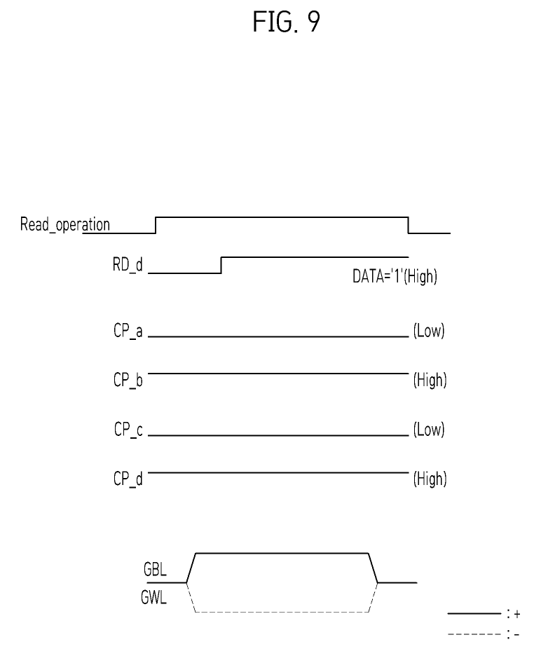

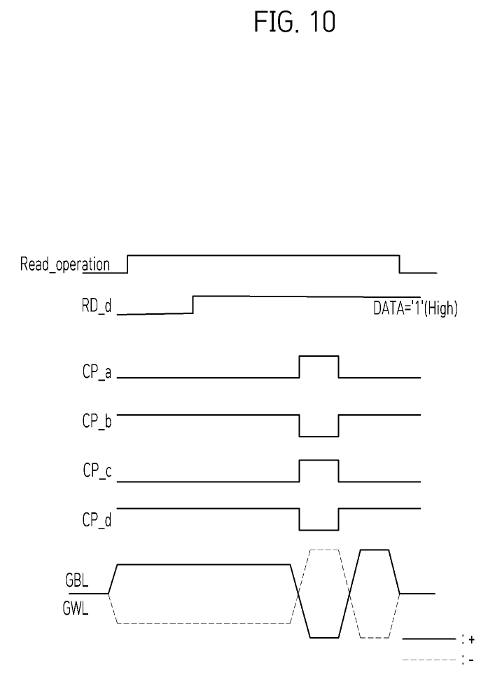

FIGS. 9 and 10 are timing diagrams for describing operations of the memory device according to embodiments of the present disclosure.

FIG. 9 may be a timing diagram when the state of the memory cell MC is determined to be the set state after the start of a read operation in the state in which the setback control signal SETBACK_en has been disabled.

After the start of a read operation, that is, during a read operation interval Read_operation, the control circuit 40 may output the first polarity change control signal CP_a being at a first level (e.g., a low level) and the second polarity change control signal CP_b being at a second level (e.g., a high level). The first polarity change control signal CP_a being at a low level may turn on the first transistor T1. The second polarity change control signal CP_b being at a high level may turn off the second transistor T2. At this time, through the first transistor T1 that has been turned on, the first voltage V_p may be transmitted to the bit line BL through the global bit line GBL. Simultaneously, the control circuit 40 may output the third polarity change control signal CP_c being a low level and the fourth polarity change control signal CP_d being at a high level. The third polarity change control signal CP_c being at a low level may turn off the third transistor T3. The fourth polarity change control signal CP_d being at a high level may turn on the fourth transistor T4. In this case, through the fourth transistor T4 that has been turned on, the second voltage V_n may be transmitted to the word line WL through the global word line GWL.

The control circuit 40 might not change the levels of the first to fourth polarity change control signals CP_a, CP_b, CP_c, and CP_d that are provided during the read operation interval Read_operation although the state of the memory cell MC is determined to be the set state DATA = 1 (High) in the state in which the setback control signal SETBACK_en has been disabled.

FIG. 10 may be a timing diagram when the state of the memory cell MC is determined to be the set state after the start of a read operation in the state in which the setback control signal SETBACK_en has been enabled.

After the start of a read operation, that is, during a read operation interval Read_operation, the control circuit 40 may output the first polarity change control signal CP_a being at a first level (e.g., a low level) and the second polarity change control signal CP_b being at a second level (e.g., a high level). The first polarity change control signal CP_a being at a low level may turn on the first transistor T1. The second polarity change control signal CP_b being at a high level may turn off the second transistor T2. At this time, through the first transistor T1 that has been turned on, the first voltage V_p may be transmitted to the bit line BL through the global bit line GBL. Simultaneously, the control circuit 40 may output the third polarity change control signal CP_c being at a low level and the fourth polarity change control signal CP_d being at a high level. The third polarity change control signal CP_c being at a low level may turn off the third transistor T3. The fourth polarity change control signal CP_d being at a high level may turn on the fourth transistor T4. At this time, through the fourth transistor T4 that has been turned on, the second voltage V_n may be transmitted to the word line WL through the global word line GWL.

When the first voltage V_p is provided to the bit line BL, the second voltage V_n is provided to the word line WL, and the state of the memory cell MC is determined to be the set state, the control circuit 40 may output the first polarity change control signal CP_a and the second polarity change control signal CP_b by changing the level of the first polarity change control signal CP_a into a high level and the level of the second polarity change control signal CP_b into a low level, respectively, during a first given (e.g. set) time interval. The first polarity change control signal CP_a being at a high level may turn off the first transistor T1. The second polarity change control signal CP_b being at a low level may turn on the second transistor T2. At this time, through the second transistor T2 that has been turned on, the first voltage V_p may be transmitted to the word line WL through the global word line GWL. Simultaneously, the control circuit 40 may output the third polarity change control signal CP_c being at a high level and the fourth polarity change control signal CP_d being at a low level during the first set time interval. The third polarity change control signal CP_c being at a high level may turn on the third transistor T3. The fourth polarity change control signal CP_d being at a low level may turn off the fourth transistor T4. At this time, through the third transistor T3 that has been turned on, the second voltage V_n may be transmitted to the bit line BL through the global bit line GBL. At this time, the memory cell MC may receive a backward pulse. For example, the first set time interval may be set sufficient to ensure that the memory cell MC in the set state is changed to a reset state while avoiding an excessive extension of a total duration of a read operation.

Thereafter, when the first set time interval elapses, the control circuit 40 may output the first polarity change control signal CP_a being at a low level and the second polarity change control signal CP_b being at a high level. The first polarity change control signal CP_a being at a low level may turn on the first transistor T1. The second polarity change control signal CP_b being at a high level may turn off the second transistor T2. At this time, through the first transistor T1 that has been turned on, the first voltage V_p may be transmitted to the bit line BL through the global bit line GBL. Simultaneously, the control circuit 40 may output the third polarity change control signal CP_c being at a low level and the fourth polarity change control signal CP_d being at a high level. The third polarity change control signal CP_c being at a low level may turn off the third transistor T3. The fourth polarity change control signal CP_d being at a high level may turn on the fourth transistor T4. At this time, through the fourth transistor T4 that has been turned on, the second voltage V_n may be transmitted to the word line WL through the global word line GWL. That is, the control circuit 40 may provide the first voltage V_p to the bit line BL, and may provide the second voltage V_n to the word line WL until the read operation interval Read_operation is terminated from a timing at which the first set time interval elapses, that is, during a second set time interval. At this time, the memory cell may receive a forward pulse. For example, the second set time interval may be set sufficient to ensure that the memory cell MC in the reset state is reverted back to the set state while avoiding an excessive extension of a total duration of a read operation.

Accordingly, the setback control signal SETBACK_en may be a signal that determines whether to provide a backward pulse and a forward pulse to a memory cell determined to be in the set state after the start of a read operation. In some embodiments, the setback control signal SETBACK_en may be asserted when a number of read operations performed without providing a backward pulse and a forward pulse to a memory cell reaches a given number (e.g., a predetermined number). In some embodiments, the setback control signal SETBACK_en may be periodically asserted at a given time interval (e.g., a predetermined time interval). In some embodiments, the setback control signal SETBACK_en may be randomly asserted.

Although some embodiments of the present disclosure have been described above with reference to the accompanying drawings, various embodiments of the present disclosure are not limited to the above-described embodiments. A person having ordinary knowledge in the art to which the present disclosure pertains may substitute, modify, and change the above-described embodiments in various ways, and such substitutions, modifications, and changes may belong to embodiments of the present disclosure.

What is claimed is:

1. An operating method of a memory device, comprising:
receiving a first read command;
providing a read voltage to a first memory cell based on the first read command;
determining whether the first memory cell is in a set state; and
providing a backward pulse to the first memory cell that has been determined to be in the set state.

2. The operating method of claim 1, further comprising providing a forward pulse to the first memory cell to which the backward pulse has been provided.

3. The operating method of claim 2, wherein a direction of a current that passes through the first memory cell when the forward pulse is provided to the first memory cell is identical with a direction of a current when the read voltage is provided to the first memory cell.

4. The operating method of claim 2, wherein the first memory cell in the set state is changed into a reset state, by providing the backward pulse to the first memory cell.

5. The operating method of claim 4, wherein the first memory cell in the reset state is changed into the set state, by providing the forward pulse to the first memory cell.

6. The operating method of claim 2, wherein:
the first memory cell is connected between a bit line and a word line;
the providing of the read voltage comprises providing the bit line with a voltage having a level higher than a voltage provided to the word line; and
the read voltage has a level between a level of a threshold voltage of a memory cell in the set state and a level of a threshold voltage of a third memory cell in a reset state.

7. The operating method of claim 6, wherein the providing of the backward pulse and the providing of the forward pulse each comprise turning on the first memory cell.

8. The operating method of claim 7, wherein the providing of the backward pulse comprises turning on the first memory cell by providing the word line with a voltage having a level higher than a voltage provided to the bit line.

9. The operating method of claim 7, wherein the providing of the forward pulse comprises turning on the first memory cell by providing the bit line with a voltage having a level higher than a voltage provided to the word line.

10. The operating method of claim 6, further comprising checking whether the first memory cell has been turned on, by providing the read voltage to the first memory cell.

11. The operating method of claim 1, wherein a direction of a current that passes through the first memory cell when the backward pulse is provided to the first memory cell is opposite to a direction of a current when the read voltage is provided to the first memory cell.

12. The operating method of claim 1, wherein the read voltage is provided to the first memory cell based on the first read command to perform a first read operation, the method further comprising:
receiving a second read command;
providing the read voltage to a second memory cell based on the second read command to perform a second read operation;
determining whether the second memory cell is in a reset state; and
terminating the second read operation without providing of the backward pulse to the second memory cell, when the second memory cell has been determined to be in the reset state.

13. A memory device, comprising:
a memory cell electrically connected between a bit line and a word line;
a voltage change circuit configured to provide a first voltage to one of the bit line and the word line and configured to provide a second voltage to the other of the bit line and the word line;
a sense amplifier configured to generate a signal indicating a state of the memory cell; and
a control circuit configured to control the voltage change circuit to provide a read voltage to the memory cell after a start of a read operation and configured to control the voltage change circuit to sequentially provide a backward pulse and a forward pulse to the memory cell based on the state of the memory cell.

14. The memory device of claim 13, wherein the first voltage has a level higher than the second voltage.

15. The memory device of claim 14, wherein when the read voltage is provided to the memory cell, the control circuit controls the voltage change circuit to provide the first voltage to the bit line and to provide the second voltage to the word line.

16. The memory device of claim 15, wherein when the backward pulse is provided to the memory cell, the control circuit controls the voltage change circuit to provide the first voltage to the word line and to provide the second voltage to the bit line during a first set time interval.

17. The memory device of claim 16, wherein when the forward pulse is provided to the memory cell, the control circuit controls the voltage change circuit to provide the first voltage to the bit line and to provide the second voltage to the word line during a second set time interval.

18. The memory device of claim 17, wherein a first difference between levels of the first voltage and the second voltage when the backward pulse is provided to the memory cell, or a second difference between levels of the first voltage and the second voltage when the forward pulse is provided to the memory cell, or both, are greater than a difference between levels of the first voltage and the second voltage after the start of the read operation.

19. A memory device, comprising:
a memory cell electrically connected between a bit line and a word line; and
a voltage supply circuit configured to receive a read command, provide a read voltage to the memory cell based on the read command, determine whether the memory cell is in a set state, and provide a backward pulse to the memory cell that has been determined to be in the set state.

20. The memory device of claim 19, wherein the voltage supply circuit is further configured to provide a forward pulse to the memory cell to which the backward pulse has been provided.
